(19) United States
(12) Patent Application Publication
(10) Pub. No.: US 2010/0276705 A1
(43) Pub. Date: Nov. 4, 2010

(54) SOLID STATE LIGHTING DEVICE WITH AN INTEGRATED FAN

(75) Inventor: Keith Scott SCOTT, Sunnyvale, CA (US)

Correspondence Address: Arent Fox LLP, 555 West Fifth Street, 48th Floor, Los Angeles, CA, 90013, US

(73) Assignee: Bridgelux, Inc.

(21) Appl. No.: 12/565,642

(22) Filed: Sep. 23, 2009

Related U.S. Application Data
(63) Continuation-in-part of application No. 12/506,026, filed on Jul. 20, 2009.

(51) Int. Cl. H01L 33/00

(52) U.S. Cl. 257/88; 257/98; 257/E33.056

(57) ABSTRACT

A solid state lighting device includes a light source having one or more solid state light emitting cells. The solid state lighting device also includes a fan to cool the light emitting cells.

### CROSS REFERENCE TO RELATED APPLICATION

The present application claims the benefit of, pursuant to 35 USC §120, U.S. patent application Ser. No. 12/506,026 entitled, “Solid State Lighting Device with an Integrated Fan,” filed Jul. 20, 2009, which is incorporated herein by reference.

### BACKGROUND

1. Field

The present disclosure relates to lighting devices, and more particularly to a solid state lighting device with an integrated fan.

2. Background

Solid state devices, such as light emitting diodes (LED)s, are attractive candidates for replacing conventional light sources such as incandescent and fluorescent lamps. LEDs have substantially higher light conversion efficiencies than incandescent lamps and longer lifetimes than both types of conventional light sources. In addition, some types of LEDs now have higher conversion efficiencies than fluorescent light sources and still higher conversion efficiencies have been demonstrated in the laboratory.

As solid state devices become more recognized by the industry as potential replacements for conventional light sources, designers will be challenged to provide solid state devices with increased luminance, which means that the power applied to these devices, will need to be greater than ever before. As a result, the ability of these solid state devices to effectively dissipate heat may be a limiting factor that influences industry wide acceptance of solid state devices as a replacement for incandescent and fluorescent light sources.

Today, there exist a number of solid state lighting devices that include an array of LEDs that function together to provide a high luminance light source. These lighting devices generally employ a heat sink to reduce the operating temperature of the LED array and increase the allowable power that may be applied. Although effective, there are a number of drawbacks to this approach. First, the heat sink is often large, thus limiting the use of a solid state lighting device in many lighting applications. Second, the heat sink is often heavy and, as result, the weight of the solid state lighting device may render it unacceptable for many lighting applications such as, by way of example, a replacement for a conventional halogen reflector lamp in a track light. Finally, heat sinks are often extruded or cast in moldings, both of which require large amounts of metal and drive up the cost of the solid state lighting device.

Accordingly, there is a need in the art for solid state lighting devices with improved designs for dissipating heat.

### SUMMARY

In one aspect of the disclosure, a solid state lighting device includes a light source having one or more solid state light emitting cells and a substrate supporting the one or more solid state light emitting cells, and a fan integrated with the light source.

In another aspect of the disclosure, a solid state lighting device includes a light source having one or more solid state light emitting cells and a substrate supporting the one or more solid state light emitting cells, and a fan thermally coupled to the light source.

In yet another aspect of the disclosure, a solid state lighting device includes a light source having one or more solid state light emitting cells and a substrate supporting the one or more solid state light emitting cells, and a fan directly attached to the light source.

In a further aspect of the disclosure, a solid state lighting device includes means for emitting light comprising one or more solid state light emitting cells, and means for cooling the one or more solid state light emitting cells, wherein the cooling means is integrated with the light emitting means.

In yet a further aspect of the disclosure, a solid state lighting device includes one or more solid state light emitting cells, and a fan having a surface supporting the one or more light emitting cells, the fan being configured to cool the one or more light emitting cells.

It is understood that other aspects of the present invention will become readily apparent to those skilled in the art from the following detailed description, wherein it is shown and described only several aspects of a solid state lighting device by way of illustration. As will be realized, the various aspects of a solid state lighting device presented throughout this disclosure are capable of modification in various other respects, all without departing from the spirit and scope of the present invention. Accordingly, the drawings and the detailed description are to be regarded as illustrative in nature and not as restrictive.

### BRIEF DESCRIPTION OF THE FIGURES

Various aspects of the present invention are illustrated by way of example, and not by way of limitation, in the accompanying drawings, wherein:

FIG. 1 is a conceptual cross-sectional side view illustrating an example of an LED;

FIG. 2 is a conceptual cross-sectional side view illustrating an example of a light source;

FIG. 3A is a conceptual top view illustrating an example of a white light source;

FIG. 3B is a conceptual cross-sectional side view of the white light source in FIG. 3A;

FIG. 4 is a conceptual cross-sectional side view of a solid state light device having a white light source;

FIG. 5 is a conceptual cross-sectional side view of a solid state light device having multiple solid state light emitting cells formed on a fan; and

FIG. 6 is a conceptual cross-sectional side view of an alternative configuration of a solid state light device having multiple solid state light emitting cells formed on a fan.

### DETAILED DESCRIPTION

The present invention is described more fully hereinafter with reference to the accompanying drawings, in which various aspects of the present invention are shown. This invention, however, may be embodied in many different forms and should not be construed as limited to the various aspects of the present invention presented throughout this disclosure. Rather, these aspects are provided so that this disclosure will be thorough and complete, and will fully convey the scope of the present invention to those skilled in the art.

The various aspects of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus or method.

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, spatially relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower”, can therefore, encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and shall not be interpreted in an idealized or overly formal sense.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Various aspects of a solid state lighting device will now be presented. However, as those skilled in the art will readily appreciate, these aspects may be extended to other light applications without departing from the spirit and scope of the invention. The solid state lighting device may include a light source that provides a means for emitting light. The light source may include one or more solid state light emitting cells mounted onto a substrate. An example of a solid state light emitting cell is an LED. The solid state lighting device may also include a fan that provides a means for cooling the solid state light emitting cells. The fan may be an electronic fan that is integrated with the light source.

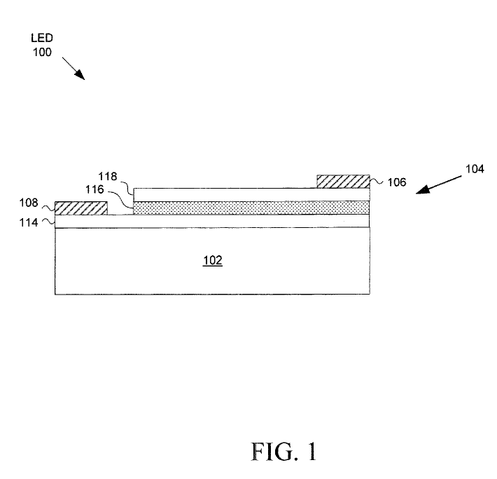

FIG. 1 is a conceptual cross-sectional side view illustrating an example of an LED. As explained above, an LED is one example of a solid state light emitting cell that may be used in various configurations of a solid state lighting device. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes, which are referred to as n-type or a p-type semiconductor region, respectively. In LED applications, the semiconductor includes an n-type semiconductor region and a p-type semiconductor region. A reverse electric field is created at the junction between the two regions, which cause the electrons and holes to move away from the junction to form an active region. When a forward voltage sufficient to overcome the reverse electric field is applied across the p-n junction, electrons and holes are forced into the active region and combine. When electrons combine with holes, they fall to lower energy levels and release energy in the form of light.

An LED generally includes a substrate, an epitaxial-layer grown on the substrate, and a pair of electrodes (e.g., anode and cathode) to apply a forward voltage across the p-n junction in the epitaxial-layer. The LED may have any one of several configurations. By way of example, the LED may have a lateral configuration with the electrodes on the same side of the epitaxial-layer, such as a typical GaN (Gallium Nitride) LED grown on an insulting sapphire substrate. An example of an LED with a lateral configuration will be presented later for the purpose of providing a complete and thorough disclosure. However, as those skilled in the art will readily appreciate, the LED may have a flip-chip configuration formed as a lateral LED that is flipped over a mounted on a submount (e.g., printed circuit board) with a substrate (that on which the epitaxial layer was grown) that can, but not necessarily, be removed after attachment of the LED to the submount. Alternatively, the LED may have a vertical configuration with the electrodes on opposite sides of the epitaxial-layer, such as a typical GaAs (Gallium Arsenide) LED grown on a conducting GaAs substrate. The LED may have a thin-film configuration with its original substrate (that on which the epitaxial-layer was grown) removed after bonding the epitaxial-layer to a new host substrate, which can be electrically conducting or insulating. The thin-film LED may have a lateral or vertical configuration. The various concepts presented throughout this disclosure are applicable to any suitable LED configuration that may be used as a light emitting cell.

Referring to FIG. 1, a lateral LED 100 includes a substrate 102, an epitaxial-layer structure 104 on the substrate 102, and a pair of electrodes 106 and 108 on the epitaxial-layer structure 104. The epitaxial-layer structure 104 comprises an active region 116 sandwiched between two oppositely doped epitaxial regions. In this example, an n-type semiconductor region 114 is formed on the substrate 102 and a p-type semiconductor region 118 is formed on the active region 116, however, the regions may be reversed. That is, the p-type semiconductor region 118 may be formed on the substrate 102 and the n-type semiconductor region 114 may formed on the active region 116. As those skilled in the art will readily appreciate, the various concepts described throughout this disclosure may be extended to any suitable epitaxial-layer structure. Additional layers (not shown) may also be included in the epitaxial-layer structure 104, including but not limited to buffer, nucleation, contact and current spreading layers as well as light extraction layers.

The electrodes 106 and 108 may be formed on the surface of the epitaxial-layer structure 104. The p-type semiconductor region 118 is exposed at the top surface, and therefore, the p-type electrode 106 may be readily formed thereon. However, the n-type semiconductor region 114 is buried beneath the p-type semiconductor region 118 and the active region 116. Accordingly, to form the n-type electrode 108 on the n-type semiconductor region 114, a portion of the active region 116 and the p-type semiconductor region 118 is removed to expose the n-type semiconductor region 114 therebeneath. After this portion of the epitaxial-layer structure 104 is removed, the n-type electrode 108 may be formed.

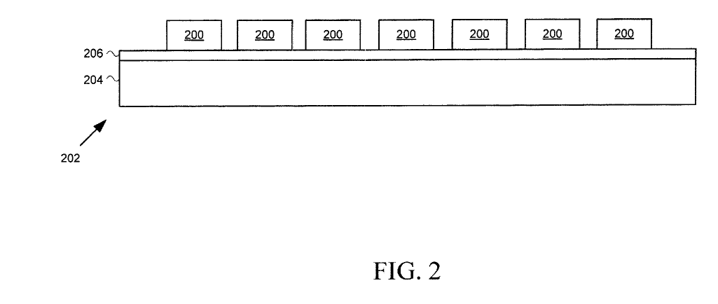

In a configuration of a solid state lighting device, a light source comprising a group of solid state light emitting cells may be used to provide increased luminance. The group of solid state light emitting cells may be implemented with an LED array or by some other suitable means. One example of a light source with an LED array will now be presented with reference to FIG. 2. FIG. 2 is a conceptual cross-sectional side view illustrating an example of a light source. In this example, a number of LEDs 200 may be formed on a substrate 202 by means well known in the art. The substrate 202 may include a base 204 and a dielectric layer 206. The base 204 provides mechanical support for the LEDs and may be made from any suitable thermally conductive material, such as, by way of example, aluminum, to dissipate heat away from the LEDs 200. The dielectric layer 206 may also be thermally conductive, while at the same time providing electrical insulation between the LEDs 200 and the base 204. The LEDs 200 may be electrically coupled in parallel and/or series by a copper circuit layer (not shown) on the dielectric layer 206.

A solid state lighting device may be configured to produce white light. White light may enable the solid state lighting device to act as a direct replacement for conventional light sources used today in incandescent, halogen and fluorescent light sources. There are at least two common ways of producing white light. One way is to use individual LEDs that emit discrete wavelengths (such as red, green, blue, amber or other colors) and then mix all the colors to produce white light. The other way is with an array of blue LEDs encapsulated with a phosphor material. The phosphor material may include, by way of example, phosphor particles suspended in an epoxy carrier or may be constructed from a soluble phosphor that is dissolved in the carrier. In this example, blue light emitted from the LEDs excites the phosphor at a high energy level and the phosphor down-converts the light to a warmer, lower energy wavelength, such as yellow light. The ratio of blue to yellow light may be chosen such that the light emitted from the LED array appears to be white, thus creating a suitable replacement for conventional incandescent and fluorescent light sources. The present invention, however, may be practiced with other LED and phosphor combinations to produce different color light.

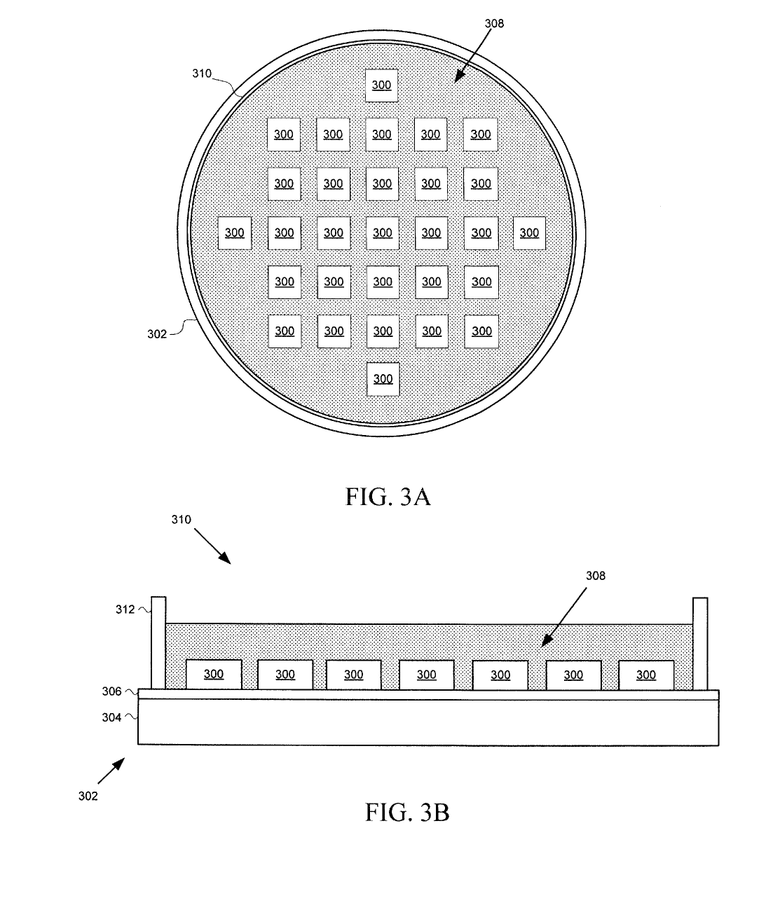

An example of a phosphor-based white light source will now be presented with reference to FIGS. 3A and 3B, however, as those skilled in the art will readily appreciate, white light may be produced in other ways. FIG. 3A is a conceptual top view of a white light source and FIG. 3B is a conceptual cross-sectional side view of the white light source in FIG. 3A. The white light source is shown with a substrate 302 which may be used to support an array of LEDs 300. The substrate 302 includes a base 304 and a dielectric layer 306. A phosphor material 308 may be deposited within a cavity 310 defined by an annular boundary 312 that extends circumferentially around the upper surface of the substrate 302. The annular boundary 312 may be formed with a suitable mold, or alternatively, formed separately from the substrate 302 and attached to the substrate 302 using an adhesive or other suitable means.

In an alternative configuration of a solid state lighting device, the white light source may be constructed from an array of LEDs, with each LED having its own phosphor layer. As those skilled in the art will readily appreciate, various configurations of LEDs and other light emitting cells may be used to create a white light source. Moreover, as noted earlier, the present invention is not limited to solid state lighting devices that produce white light, but may be extended to solid state lighting devices that produce other colors of light.

The solid state lighting device may include a fan to dissipate heat away from the light source. The fan may be an electronic fan or some other suitable device that generates airflow to cool the light source. An electronic fan is a device used to produce airflow with no moving parts. An electronic fan generally exploits the concept of corona wind. Corona wind is a physical phenomenon that is produced by a strong electric field. These strong electric fields are often found at the tips of electrical conductors where electric charges, which reside entirely on the surface of the conductor, tend to accumulate. When the electric field reaches a certain strength, known as the corona discharge inception voltage gradient, the surrounding air is ionized with the same polarity as the tip of the conductor. The tip then repels the ionized air molecules surrounding it, thereby creating airflow. A non-limiting example of an electronic fan that exploits corona wind to generate airflow is an RSD5 solid-state fan developed by Thorrn Micro Technologies, Inc (also called, Ventiva).

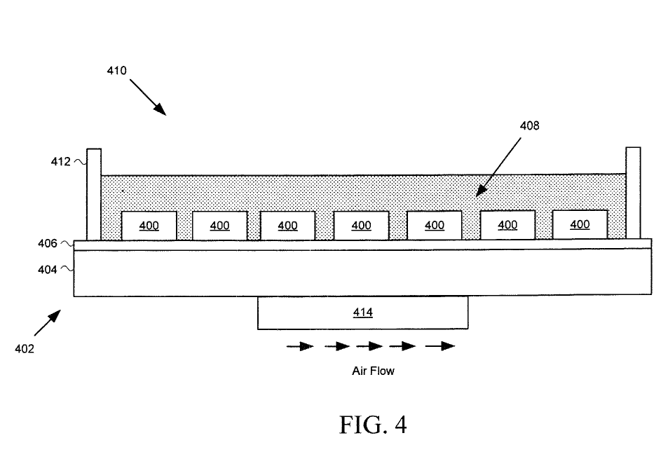

In one configuration of a solid state lighting device, the fan may be integrated with the light source. An example of such device will now be presented with reference to FIG. 4. FIG. 4 is a conceptual cross-sectional side view of a solid state light device having a white light source. The solid state light emitting device is similar to that described in connection with FIGS. 3A and 3B, with a substrate 402 having a base 404 and a dielectric layer 406 and an array of LEDs 400 supported by the substrate 402. A cavity 410 is formed by an annular boundary 412 that contains a phosphor material 408 to produce a white light source.

In this example, a fan 414 is integrated with the light source by attaching the fan 414 to the base 404 of the substrate 402, either directly as shown of through one or more of the intervening layers. Preferably, the fan 414 is thermally coupled to the base 404, whether directly attached or through intervening layers, to facilitate cooling of the light source by providing a thermally conductive path between the LEDs 400 and the substrate 402. The fan 414 may be bonded, deposited, connected, coupled, fabricated, or otherwise attached to the light source. By way of example, the fan 414 may be bonded to the base 404 of the substrate 402 with a thermally conductive adhesive.

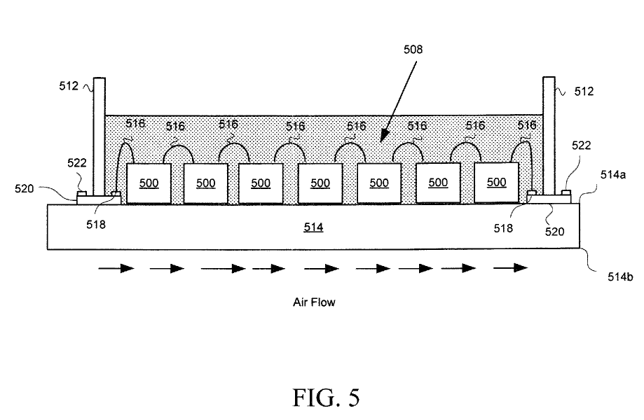

In another configuration of a solid state lighting device, a group of light emitting cells may formed on the fan, either directly or though one or more intervening layers. An example of this configuration will now be presented with reference to FIG. 5. In this example, the fan 514 includes a bottom surface 514b containing a series of electrical conductors (not shown) that are used to create air flow in a manner discussed earlier in this disclosure. The fan 514 also includes an upper surface 514a that supports a number of LEDs 500. The LEDs 500 may have a dielectric substrate 102 (see FIG. 1), such as sapphire or the like, which allows the LEDs 500 to be formed directly on the upper surface 514a of the fan 514. A thermally conductive epoxy, or other suitable adhesive material, may be used to bond the LEDs 500 to the fan 514.

In the case of a fan supporting blue LEDs, a phosphor material 508 may be deposited within a cavity 510 defined by a boundary 512 that extends around the upper surface 514a of the fan 514. The boundary 512 may be formed separately from the fan 514 and attached to the upper surface 514a using an adhesive or other suitable means.

The LEDs 500 may be connected, in parallel and/or series, by wires 516. Some of the wires 516 may be connected to electrical contacts 518 on dielectric pads 520, which extend across the annular boundary 512. Electrical contacts 522 located on the dielectric pads 520 outside the annular boundary 512 may be connected to the electrical contacts 518 through a copper traces (not shown) embedded in the dielectric pads 520. The electrical contacts 518 may be used to provide power to the LEDs 500 and/or connect the LEDs 500 to other circuitry.

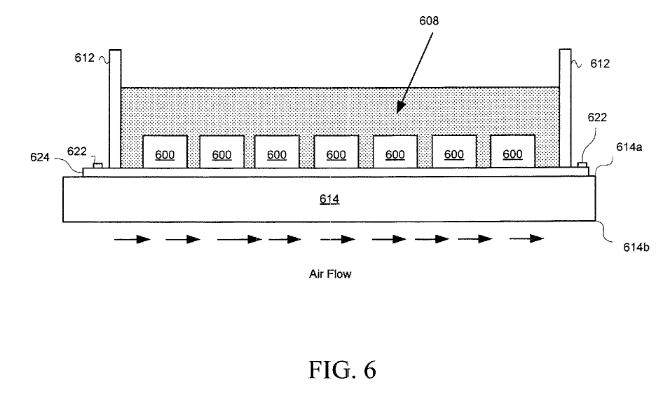

Alternatively, a dielectric layer may be formed between upper surface of the fan and the LEDs. An example of this configuration is shown in FIG. 6. In this configuration, a dielectric layer 624 provides electrical insulation to LEDs 600, thus allowing the use of LEDs with either an electrically conductive substrate 102 (see FIG. 1) or a dielectric substrate 102 (see FIG. 1). The LEDs 600 may be electrically coupled in parallel and/or series through a copper circuit layer (not shown) on the dielectric layer 624. The copper traces (not shown) on the dielectric layer 624 may extend across the boundary 612 and terminate at electrical contacts 622 to provide a means by which power may be applied to the LEDs 600 and/or the LEDs 600 may be coupled to other circuitry. In the case of blue LEDs, a phosphor material 608 may be deposited in the cavity formed by the boundary 612.

Solid state lighting devices with integrated fans have numerous applications. By way of example, these solid state lighting devices may be used to replace an incandescent lamp or the filament in conventional incandescent light bulbs for household, commercial, portable (e.g., table lamps, automotive headlamps, flashlights, etc.), decorative and advertising lighting applications. These solid state lighting devices may also be used as light sources for other conventional lamps, including, by way of example, gas discharge lamps (e.g., compact fluorescent lamps), including high-intensity discharge lamps. Those skilled in the art will readily appreciate that the various concepts presented throughout this disclosure may be extended to numerous lighting applications.

The various aspects of a solid state lighting device are provided to enable one of ordinary skill in the art to practice the present invention. Various modifications to, and alternative configurations of the solid state lighting devices presented throughout this disclosure will be readily apparent to those skilled in the art, and the concepts disclosed herein may be extended to other lighting applications. Thus, the claims are not intended to be limited to the various aspects of this disclosure, but are to be accorded the full scope consistent with the language of the claims.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

1-38. (canceled)

39. A solid state lighting device, comprising:
one or more solid state light emitting cells; and
a fan having a surface supporting the one or more light emitting cells, the fan being configured to cool the one or more light emitting cells.

40. The solid state lighting device of claim 39 wherein the one or more light emitting cells are electrically coupled together.

41. The solid state lighting device of claim 40 further comprising a dielectric having at least one electrical contact electrically coupled to the light emitting cells.

42. The solid state light emitting device of claim 41 wherein the dielectric comprises a dielectric layer between the light emitting cells and the surface of the fan.

43. The solid state light emitting device of claim 41 wherein the dielectric comprises a dielectric pad, and wherein the light emitting cells are formed directly on the surface of the fan.

44. The solid state light emitting device of claim 41 further comprising a boundary formed around the light emitting cells, and wherein the dielectric extends across the boundary.

45-50. (canceled)

51. A solid state lighting device, comprising:
means for emitting light comprising one or more solid state light emitting cells;
means for cooling the one or more solid state light emitting cells, wherein the cooling means is integrated with the light emitting means.

52. The solid state lighting device of claim 51 wherein the light emitting means comprises a substrate having opposing surfaces, and wherein the one or more light emitting cells are supported on one of the surfaces of the substrate and the cooling means is integrated with the other one of the surfaces of the substrate.

53. The solid state lighting device of claim 51 wherein the substrate comprises a thermally conductive base and a thermally conductive dielectric layer on the base, the one or more light emitting cells being attached to the dielectric layer and the cooling means being integrated with the base.

54. The solid state lighting device of claim 53 wherein the dielectric layer includes an electrically conductive circuit layer connecting the one or more light emitting cells to one another, the dielectric layer providing electrical insulation between the circuit layer and the base.

55. The solid state lighting device of claim 51 wherein the cooling means comprises an electronic fan.

56. The solid state lighting device of claim 51 wherein the cooling means comprises a thermally conductive base attached to the substrate of the means for emitting light.

57. The solid state lighting device of claim 51 wherein the cooling means is configured to generate corona wind.

58. The solid state lighting device of claim 51 wherein the light emitting means comprises phosphor, the one or more light emitting cells being arranged to emit light through the phosphor.

59. The solid state light emitting device of claim 44 wherein said at least one electrical contact comprises a first electrical contact outside the boundary and a second electrical contact inside the boundary, the first and second electrical contacts being electrically coupled together, and wherein the second electrical contact is wired to at least one of the light emitting cells.

60. The solid state lighting device of claim 39 wherein the fan comprises an electronic fan.

61. The solid state lighting device of claim 39 wherein the fan comprises a second surface opposite the surface supporting the one or more light emitting cells, wherein the fan is further configured to generate a corona wind along the second surface.

62. The solid state lighting device of claim 39 further comprising phosphor, the one or more light emitting cells being arranged on the fan to emit light through the phosphor.

63. The solid state lighting device of claim 39 wherein the one or more light emitting cells are configured to emit different wavelengths that combine to produce white light.

64. The solid state lighting device of claim 63 further comprising a boundary formed around the light emitting cells to form a cavity, and wherein the phosphor material is in the cavity.
